(19) United States
(12) Patent Application Publication
(10) Pub. No.: US 2025/0273596 A1
(43) Pub. Date: Aug. 28, 2025

(54) INTEGRATED CIRCUIT (IC) PACKAGES EMPLOYING STIFFENER STRUCTURE WITH INTEGRATED CAVITY(IES) TO ENCLOSE AN ELECTRICAL COMPONENT(S), AND RELATED FABRICATION METHODS

(71) Applicant: QUALCOMM Incorporated, San Diego, CA (US)

(72) Inventors: Sun Woong Yun, San Diego, CA (US); Joan Rey Villarba Buot, Escondido, CA (US); Zhijie Wang, San Diego, CA (US)

(21) Appl. No.: 18/589,093

(22) Filed: Feb. 27, 2024

(51) Int. Cl. H01L 23/00; H01L 23/367; H01L 25/16

(52) U.S. Cl. CPC H01L 23/562; H01L 23/3675; H01L 24/26; H01L 24/32; H01L 25/16; H01L 24/16; H01L 24/33; H01L 24/73; H01L 2224/16225; H01L 2224/26175; H01L 2224/32225; H01L 2224/32245; H01L 2224/33181; H01L 2224/73204; H01L 2224/73253

(57) ABSTRACT

Integrated circuit (IC) packages employing a stiffener structure substrate with integrated cavity(ies) to enclose an electrical component(s), and related fabrication methods are disclosed. The IC package includes a stiffener structure coupled to a first side of the package substrate to increase stiffness of the package substrate, which in turn increases stiffness of the IC package to avoid/reduce warpage. The stiffener structure includes an integrated cavity(ies) extending to the first side of the package substrate and encompasses an electrical component coupled to the first side of the package substrate. In this manner, the stiffener structure does not have to be fully displaced outside of the electrical component to provide room for both the stiffener structure and the electrical component on the package substrate. This area savings can be used to increase stiffener structure size for increased stiffness and without increasing IC package size, or reduce the IC package size.

### BACKGROUND

### I. Field of the Disclosure

The field of the disclosure relates to integrated circuit (IC) packages, and more particularly to adding stiffener structures to the IC package to increase stiffness and in turn reduce or avoid warpage.

### II. Background

Integrated circuits (ICs) are the cornerstone of electronic devices. ICs are typically packaged in an IC package, also called a “semiconductor package” or “chip package.” The IC package includes a package substrate and one or more semiconductor dies (“dies”) (e.g., in the form of a chip) or other electronic modules mounted to the package substrate to provide electrical connectivity to the die(s). For example, a die in an IC package may be a system-on-a chip (SoC). The dies are electrically coupled to another die(s) and/or to other components in the IC package through electrical coupling to metal lines in the package substrate. The dies can also be electrically coupled to other circuits outside the IC package through electrical connections of external metal interconnects (e.g., solder bumps) of the IC package. The IC package may also include passive electrical components coupled to the package substrate outside of the die(s), but electrically coupled to a die(s) to form part of the circuits of the IC die. These passive components may not be included within the IC die due to size limitations. For example, such a passive electrical component could be a capacitor that is used to provide a decoupling capacitance to shunt noise in power signals to reduce its effect on the IC die(s). Another example of such a passive electrical component is an inductor.

Providing an IC package with multiple components such as dies and passive electrical components increases the size of the IC package. The package substrate must be large enough to support the multiple components being mounted on the package substrate. The components may also require adjacent keep-out-zones (KoZ) to provide benefits such as providing buffer areas to prevent interference or damage from neighboring components such as from their underfill material, thermal management, and/or reduction in signal interference. However, an increased IC package size can make the IC package more susceptible to warpage from a force applied to the IC package, which in turn can lead to solder joint cracking or failure between the components and the package substrate.

### SUMMARY OF THE DISCLOSURE

Aspects disclosed herein include integrated circuit (IC) packages employing a stiffener structure with an integrated cavity(ies) to enclose an electrical component(s). Related fabrication methods are also disclosed. The IC package includes a package substrate that extends in a first, lateral direction and one or more semiconductor dies (“dies”) coupled to a first side of the package substrate. The IC package also includes one or more electrical components (e.g., a passive electrical component, another die or IC chip) coupled to the first side of the package substrate. The IC package also includes a stiffener structure that is coupled to the first side of the package substrate and that extends in a second, vertical direction from the package substrate. A stiffener structure is a structure made from one or more materials with higher mechanical strength, such as a metal or composite material that can be coupled or attached to a package substate to add and increase the stiffness of the package substrate, which in turn increases the stiffness of the IC package to avoid or reduce warpage. In exemplary aspects, the stiffener structure includes one or more integrated cavities that each extend to the first side of the package substrate. The stiffener structure is coupled to the first side of the package substrate such that the cavity encompasses an electrical component coupled to the first side of the package substrate. In an example, the cavity and the first side of the package substrate fully encompass the electrical component. In this manner, the stiffener structure does not have to be fully displaced outside of the electrical component in the first, lateral direction, to provide room for both the stiffener structure and the electrical component. In one example, this can allow the stiffener structure to be expanded in width in the first, lateral direction to increase the stiffness of the IC package without having to enlarge the size of the package substrate and IC package in the first, lateral direction. In another example, this can allow the package substrate to be reduced in width by relocating the stiffener structure to at least partially intersect a vertical area of the electrical component, thereby reducing the size of the IC package.

In another exemplary aspect, encompassing an electrical component in the cavity of the stiffener structure can also allow the electrical component to be more closely located to a die in the first lateral direction thereby reducing signal routing distance and reducing signal resistance and/or inductance. This is because an outer side wall of the stiffener structure between its cavity and the other electrically-coupled die can act as an underfill material shield or dam to prevent an underfill material disposed around the die from interfering with the electrical component encompassed in the cavity. Thus, a larger lateral keep-out-zone (KoZ) is not required between the electrical component and the die coupled to the package substrate, thus allowing the electrical component to be coupled closer to the die in the first, lateral direction. In an exemplary fabrication method, the stiffener structure is coupled to the package substrate such that its cavity encompasses the electrical component, before an underfill material is disposed around the die. The underfill material is then disposed around the die. In this manner, the outer side wall of the stiffener structure present between its cavity and the other electrically-coupled die provides the underfill material shield or dam to prevent or reduce the underfill material from interfering with the electrical component.

In another exemplary aspect, the stiffener structure can be provided in the form of a stiffener ring that is disposed in a closed structure around or adjacent to a perimeter of the package substrate and coupled to the package substrate. The stiffener ring is a ring-shaped stiffener structure that is coupled to the first, outer side of the package substrate and extends from the package substrate in the second, vertical direction. One or more cavities are disposed in the ring-shaped stiffener structure that can encompass an electrical component(s) when coupled to the package substrate. As discussed above, an outer side wall of the stiffener ring between its cavity(ies) and the other electrically-coupled die can act as a underfill material shield or dam to prevent an underfill material disposed around the die from interfering with the electrical component encompassed in the cavity, allowing a reduced lateral distance between the encompassed electrical component and the electrically-coupled die to reduce signal routing distance. In another exemplary aspect, the stiffener structure can be an open structure that is not in the form of a ring structure, but rather includes one or more structures that are coupled to the package substrate to add stiffness, and any of which that can include a cavity(ies) to encompass an electrical component(s).

In another exemplary aspect, the stiffener structure is a heat spreader that includes a lid or cover structure located adjacent to one or more dies coupled to the package substrate. The heat spreader includes a stiffener structure(s) that extend down from the lid or cover structure as a monolithic structure (e.g., created from a mold) and are coupled to the package substrate to support the lid or cover structure being disposed adjacent to the die(s) to dissipate heat generated from the die(s). In this regard, one or more of the stiffener structure(s) of the heat spreader include an integrated cavity that encompasses an electrical component(s) coupled to the package substrate.

In another exemplary aspect, the stiffener structure can be provided as part of a heat spreader coupled to the package substrate and a separate lid or cover structure coupled to the stiffener structure. This is opposed to a monolithic heat spreader. This form of a heat spreader allows stiffener structure(s) to be coupled to the package substrate with their cavity(ies) encompassing an electrical component(s) on the package substrate first, before the lid or cover structure is coupled to the stiffener structure(s). In this manner, the die area of the package substrate is still open such that an underfill material can then be disposed around a die(s) coupled to the package substrate. The outer side wall of the stiffener structure(s) between its cavity and the die(s) is present to provide the underfill material shield or dam like discussed above. After the underfill material is disposed around the die(s), the lid or cover structure can then be subsequently coupled to the stiffener structure(s) to completely form a heat spreader and encompass the die(s) within the heat spreader.

In this regard, in one exemplary aspect, an IC package is provided. The IC package comprises a package substrate comprising a first side extending in a first direction. The IC package also comprises a first die coupled to the first side of the package substrate. The IC package also comprises a first stiffener structure adjacent to the first die in the first direction and coupled to the first side of the package substrate. The first stiffener structure comprises a first cavity extending adjacent to the first side of the package substrate. The IC package also comprises a first electrical component coupled to the first side of the package substrate, the first electrical component at least partially embedded in the first cavity.

In another exemplary aspect, a method of fabricating an IC package is provided. The method comprises providing a package substrate comprising a first side extending in a first direction. The method also comprises coupling a first electrical component to the first side of the package substrate. The method also comprises coupling a first surface of a first stiffener structure comprising a first cavity extending adjacent to the first surface, to the first side of the package substrate such that the first cavity at least partially encloses the first electrical component. The method also comprises coupling a first die to the first side of the package substrate adjacent to the first stiffener structure in the first direction.

### BRIEF DESCRIPTION OF THE FIGURES

FIGS. 1A and 1B are respective side and top perspective views of an exemplary integrated circuit (IC) package that includes multiple semiconductor dies (“dies”) and die-side decoupling capacitors mounted to a package substrate and further includes an outer metal stiffener ring structure to add stiffness to the IC package to reduce or avoid warpage;

FIGS. 2A and 2B are respective side and top views of an exemplary IC package that includes a stiffener structure in the form of a stiffener ring coupled to a first side of a package substrate to increase stiffness of the IC package, and wherein the stiffener ring includes an integrated closed cavity extending to the first side of the package substrate and encompassing electrical components coupled to the first side of the package substrate;

FIGS. 3A and 3B are respective side and top views of an exemplary IC package that includes a stiffener structure in the form of a stiffener ring coupled to a first side of a package substrate to increase stiffness of the IC package, and wherein the stiffener ring includes an integrated open cavity extending to the first side of the package substrate and encompassing electrical components coupled to the first side of the package substrate;

FIGS. 4A and 4B are respective side and top views of another exemplary IC package that includes a stiffener structure in the form of a heat spreader that includes a ring-shaped stiffener structure coupled to a first side of a package substrate to increase stiffness of the IC package and to support a separate lid structure coupled to the stiffener structure to provide a heat spreader, and wherein the ring-shaped stiffener structure includes an integrated cavity extending to the first side of the package substrate and encompassing electrical components coupled to the first side of the package substrate;

FIGS. 5A and 5B are respective side and top views of another exemplary IC package that includes a stiffener structure in the form of a heat spreader that includes a ring-shaped stiffener structure coupled to a first side of a package substrate to increase stiffness of the IC package and to support a lid structure coupled to the stiffener as a monolithic structure to provide a heat spreader, and wherein the ring-shaped stiffener structure includes an integrated cavity extending to the first side of the package substrate and encompassing electrical components coupled to the first side of the package substrate;

FIG. 6 is a flowchart illustrating an exemplary process of fabricating an IC package that includes a stiffener structure coupled to a first side of a package substrate to increase stiffness of the IC package, and wherein the stiffener structure includes an integrated cavity(ies) extending to the first side of the package substrate and encompassing an electrical component(s) coupled the first side of the package substrate, including, but not limited to, the IC packages in FIGS. 2A-5B;

FIGS. 7A and 7B is a flowchart illustrating another exemplary fabrication process of fabricating the exemplary IC package in FIGS. 2A and 2B that includes a stiffener structure in the form of a stiffener ring coupled to a first side of a package substrate to increase stiffness of the IC package, and wherein the stiffener ring includes an integrated cavity extending to the first side of the package substrate and encompassing electrical components coupled to the first side of the package substrate;

FIGS. 8A-8C are exemplary fabrication stages during fabrication of the IC package according to the exemplary fabrication process in FIGS. 7A and 7B;

FIGS. 9A-9C is a flowchart illustrating another exemplary fabrication process of fabricating the exemplary IC package in FIGS. 4A and 4B that includes a stiffener structure in the form of a heat spreader that includes a ring-shaped stiffener structure coupled to a first side of a package substrate to increase stiffness of the IC package and to support a separate lid structure coupled to the stiffener structure to provide a heat spreader, and wherein the ring-shaped stiffener structure includes an integrated cavity extending to the first side of the package substrate and encompassing electrical components coupled to the first side of the package substrate;

FIGS. 10A-10E are exemplary fabrication stages during fabrication of the IC package according to the exemplary fabrication process in FIGS. 9A-9C;

FIGS. 11A and 11B is a flowchart illustrating another exemplary fabrication process of fabricating the exemplary IC package in FIGS. 5A and 5B that includes a stiffener structure in the form of a heat spreader that includes a ring-shaped stiffener structure coupled to a first side of a package substrate to increase stiffness of the IC package and to support a lid structure coupled to the stiffener as a monolithic structure to provide a heat spreader, and wherein the ring-shaped stiffener structure includes an integrated cavity extending to the first side of the package substrate and encompassing electrical components coupled to the first side of the package substrate;

FIGS. 12A-12D are exemplary fabrication stages during fabrication of the IC package according to the exemplary fabrication process in FIGS. 11A and 11B;

FIG. 13 is a block diagram of an exemplary wireless communications device that includes one or more IC packages that include a stiffener structure coupled to a first side of a package substrate to increase stiffness of the IC package, and wherein the stiffener structure includes an integrated cavity(ies) extending to the first side of the package substrate and encompassing an electrical component(s) coupled to the first side of the package substrate, including, but not limited to, the IC packages in FIGS. 2A-5B, 8C, 10E, and 12D, and that can be fabricated according to a fabrication process, including, but not limited to, the exemplary fabrication processes in FIGS. 6, 7A-7B, 9A-9C, and 11A-11B; and

FIG. 14 is a block diagram of an exemplary electronic device in the form of a processor-based system that can include one or more IC packages that include a stiffener structure coupled to a first side of a package substrate to increase stiffness of the IC package, and wherein the stiffener structure includes an integrated cavity(ies) extending to the first side of the package substrate and encompassing an electrical component(s) coupled to the first side of the package substrate, including, but not limited to, the IC packages in FIGS. 2A-5B, 8C, 10E, and 12D, and that can be fabricated according to a fabrication process, including, but not limited to, the exemplary fabrication processes in FIGS. 6, 7A-7B, 9A-9C, and 11A-11B.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed herein include integrated circuit (IC) packages employing a stiffener structure with an integrated cavity(ies) to enclose an electrical component(s). Related fabrication methods are also disclosed. The IC package includes a package substrate that extends in a first, lateral direction and one or more semiconductor dies (“dies”) coupled to a first side of the package substrate. The IC package also includes a stiffener structure that is coupled to the first side of the package substrate and that extends in a second, vertical direction from the package substrate. A stiffener structure is a structure made from one or more materials with higher mechanical strength, such as a metal or composite material that can be coupled or attached to a package substate to add and increase the stiffness of the package substrate, which in turn increases the stiffness of the IC package to avoid or reduce warpage. In exemplary aspects, the stiffener structure includes one or more integrated cavities that each extend to the first side of the package substrate. The stiffener structure is coupled to the first side of the package substrate such that the cavity encompasses an electrical component coupled to the first side of the package substrate. In an example, the cavity and the first side of the package substrate fully encompass the electrical component. In this manner, the stiffener structure does not have to be fully displaced outside of the electrical component in the first, lateral direction, to provide room for both the stiffener structure and the electrical component. In one example, this can allow the stiffener structure to be expanded in width in the first, lateral direction to increase the stiffness of the IC package without having to enlarge the size of the package substrate and IC package in the first, lateral direction. In another example, this can allow the package substrate to be reduced in width by relocating the stiffener structure to at least partially intersect a vertical area of the electrical component, thereby reducing the size of the IC package.

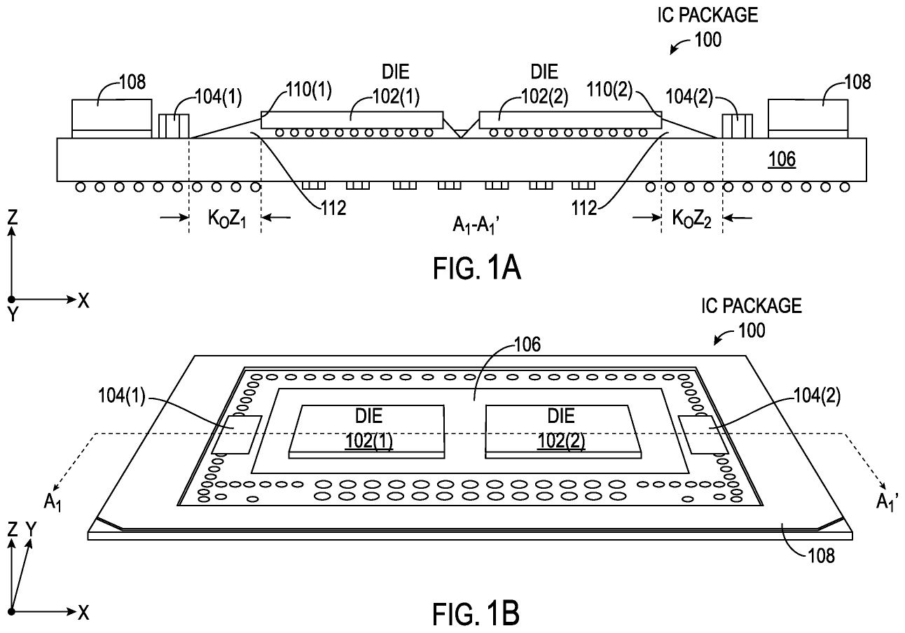

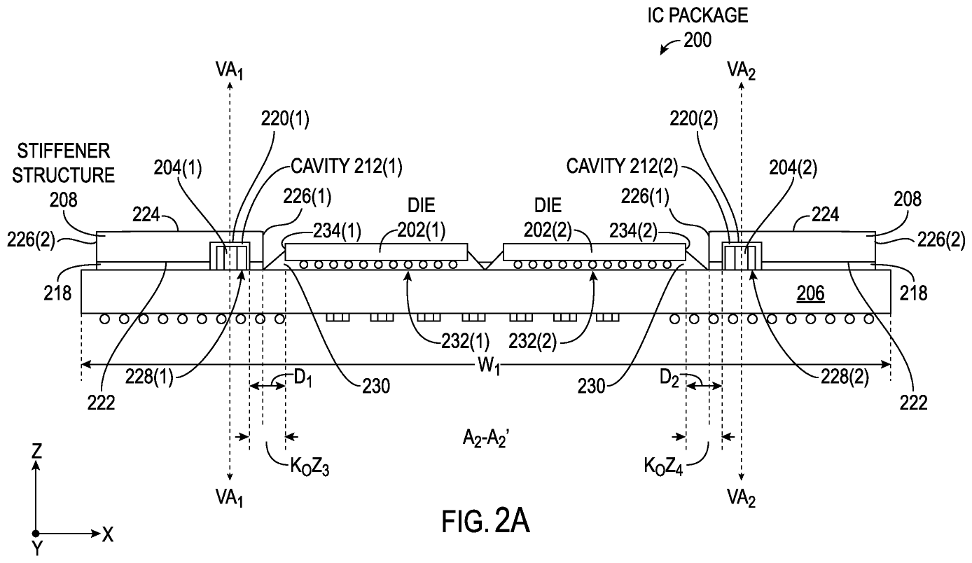

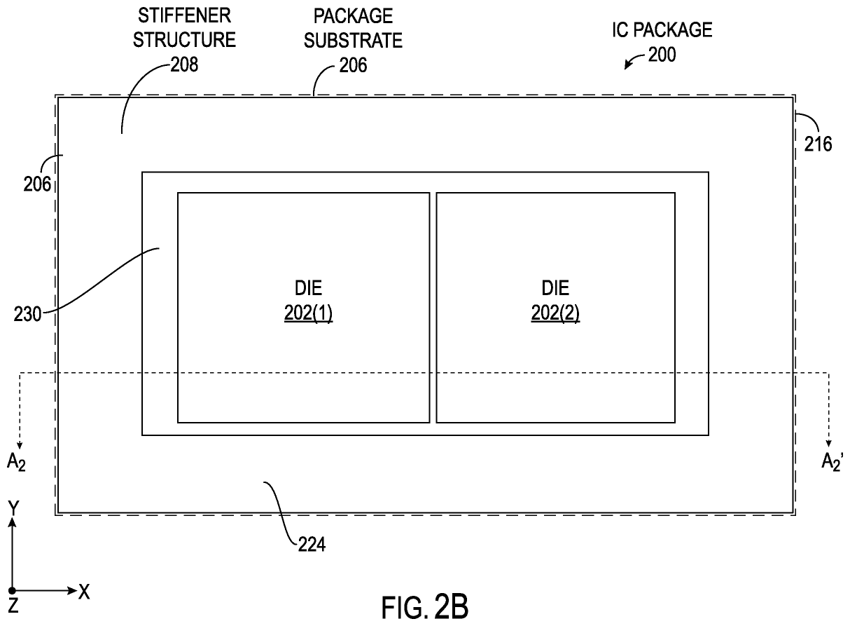

Before discussing examples of IC packages that include a stiffener structure coupled to a first side of a package substrate to increase stiffness of the IC package, and wherein the stiffener structure includes an integrated cavity(ies) extending to the first side of the package substrate and encompassing an electrical component(s) coupled to the first side of the package substrate starting at FIG. 2A, an example of an IC package that does not include a stiffener structure encompassing an electrical component is first discussed with regard to FIGS. 1A and 1B.

In this regard, FIGS. 1A and 1B are respective side and top perspective views of an exemplary integrated circuit (IC) package 100 that includes multiple semiconductor dies (“dies”) 102(1), 102(2) and die-side capacitors 104(1), 104(2) mounted to a package substrate 106. The side view of the IC package 100 in FIG. 1A is a cross-sectional view across the A₁-A₁′ cross-section line in the IC package 100 in FIG. 1B. The capacitors 104(1), 104(2) are examples of electrical components. The capacitors 104(1), 104(2) may be coupled to circuits in the dies 102(1) and/or 102(2) through signal routing paths through the package substrate 106 to shunt noise from one electrical circuit (e.g., a power supply circuit) to another electrical circuit (e.g., a powered electrical circuit). As another example, the capacitors 104(1), 104(2) may form part of a filtering circuit in the dies 102(1) and/or 102(2). The IC package 100 also includes an outer metal ring stiffener structure 108 to add stiffness to the package substrate 106 to add stiffness to the IC package 100 to reduce or avoid warpage.

As shown in FIG. 1A, the capacitors 104(1), 104(2) are laterally displayed in a first, horizontal direction (X-axis, Y-axis directions) from respective side walls 110(1), 110(2) of the dies 102(1), 102(2) so that the capacitors 104(1), 104(2) are outside respective keep-out-zones KOZ₁, KOZ₂ for the dies 102(1), 102(2). The keep-out-zones KOZ₁, KOZ₂ in this example are areas that are designed to remain free from interference from other components so that an underfill material 112 can be disposed underneath and adjacent to the dies 102(1), 102(2) to reinforce their stability and their solder joints to the package substrate 106. However, providing these keep-out-zones KOZ₁, KOZ₂ increases the lateral width of the package substrate 106 in the first, horizontal direction (X-axis and/or Y-axis directions), because the capacitors 104(1), 104(2) and the stiffener structure 108 must be laterally displaced outside of the respective keep-out-zones KOZ₁, KOZ₂ in the first, horizontal direction (X-axis and/or Y-axis directions). This leads to an increase in the size of the package substrate 106, which in turn leads to an increase in the size of the overall IC package 100, which may be undesirable, especially for mobile device applications where minimizing IC package size is important. The stiffener structure 108 could be reduced in size or width in the first, horizontal direction (X-axis and/or Y-axis directions) to allow for a smaller size package substrate 106 in the IC package 100. However, this may reduce the added stiffness to the package substrate 106 making it and the IC package 100 more susceptible to warpage and resulting damage in an undesired manner.

In this regard, FIGS. 2A and 2B are respective side and top views of an exemplary IC package 200 that includes first and second dies 202(1), 202(2) and a stiffener structure 208 that has first and second cavities 212(1), 212(2) for encompassing respective electrical component(s) 204(1), 204(2) coupled to a package substrate 206. As discussed in more detail below, the stiffener structure 208 is a structure made from one or more materials with higher mechanical strength, such as a metal or composite material that can be coupled or attached to the package substate 206 to add and increase the stiffness of the package substrate 206, which in turn increases the stiffness of the IC package 200 to avoid or reduce warpage. The stiffener structure 208 and its first and second cavities 212(1), 212(2) have respective vertical axes VA₁, VA₂ that intersect the respective electrical components 204(1), 204(2) in a second, vertical direction (Z-axis direction) orthogonal to the first, horizontal direction (X-axis and/or Y-axis directions). The stiffener structure 208 is located outside the first and second dies 202(1), 202(2) in the first, horizontal direction (X-axis and/or Y-axis directions) and neither it nor its first and second cavities 212(1), 212(2) intersects either the first or second die 202(1), 202(2) in the second, vertical direction (Z-axis direction). In this example, as shown in FIG. 2B, the stiffener structure 208 is a single structure that is a ring-shaped stiffener structure that is adjacent to the perimeter 216 of the package substrate 206, but such is not required. The stiffener structure 208 could be a structure segment that is not a closed shaped or multiple structures that each include the respective first and second cavities 212(1), 212(2) encompassing the respective first and second electrical components 204(1), 204(2). As discussed in more detail below, this provides additional area for the stiffener structure 208 and electrical components 204(1), 204(2) to not have to be fully displaced from each other in the first, horizontal direction (X-axis and/or Y-axis directions) such that the package substrate 206 has to be enlarged in width in the first, horizontal direction (X-axis and/or Y-axis directions) to support both the stiffener structure 208 and the electrical components 204(1), 204(2).

In this manner, in one example, the package substrate 206 can be reduced in width W₁ in the first, horizontal direction (X-axis and/or Y-axis directions) with the area saved by the electrical components 204(1), 204(2) being embedded in the first and second cavities 212(1), 212(2) of the stiffener structure 208 to provide for a reduced size IC package 200, while still providing for the electrical components 204(1), 204(2) and stiffener structure 208 to be provided in the IC package 200. In another example, providing the first and second cavities 212(1) and/or 212(2) in the stiffener structure 208 that encompass the electrical components 204(1), 204(2) can allow the stiffener structure 208 to be expanded in width in the first, horizontal direction (X-axis and/or Y-axis directions) to increase the stiffness of the IC package 200 without having to enlarge the size of the package substrate 206 and the IC package 200 in the first, horizontal direction (X-axis and/or Y-axis directions) like shown in the IC package 100 in FIGS. 1A and 1B for example.

Note that the example IC package 200 in FIGS. 2A and 2B includes multiple dies 202(1), 202(2), but such is not required. The IC package 200 could include any number of dies desired. Also note that the IC package includes multiple cavities 212(1), 212(2), but such is not required. The IC package 200 could include any number of cavities. Also note that the first and second cavities 212(1), 212(2) could be provided as a single, common cavity that is continuous through the stiffener structure 208 in the form of a channel structure for example. Also note that the stiffener structure 208 shown in FIG. 2A could be two separate stiffener structures that are provided independently of each other with their separate respective first and second cavities 212(1), 212(2) to encompass the respective first and second electrical components 204(1), 204(2).

With reference to FIG. 2A, in this example, the first and second dies 202(1), 202(2) are coupled to a first side 214(1) of the package substrate 206. For example, the first and second dies 202(1), 202(2) can be discrete, modular dies that are chiplets coupled to the package substrate 206 and electrically coupled to each other using die-to-die connections provided through the package substrate 206. The dies 202(1), 202(2) as chiplets can include circuitry that is specific to a task or functionality, as opposed to, for example, a system-on-a-chip (SoC) that includes multiple systems and functions on a single, monolithic die. As process node continues to scale and die size increases, reducing the cost of yield loss becomes more challenging. Thus, by breaking a large monolithic die into chiplets, such as the dies 202(1), 202(2), cost due to yield loss is reduced. Chiplets can facilitate an IC package's faster time to market as chiplets allow already proven and tested dies to be integrated with other chiplets in the IC package. Chiplets also allow for dies, such as the dies 202(1), 202(2), from different manufacturers to be integrated together in the same package for heterogeneous integration, such as in the IC package 200. Using chiplets in an IC package, including the IC package 200, also facilitates the ability to use fabrication technologies and processes of choice to fabricate the first and second dies 202(1), 202(2) as either from the same or different technology nodes.

For example, the first die 202(1) as a chiplet may be fabricated using a first technology node, and the second die 202(2) as a chiplet may be fabricated using a second technology node that is not as advanced as the first technology node. In such an example, the first die 202(1) may include components (e.g., interconnects, transistors) that have a first minimum size, and the second die 202(2) may include components (e.g., interconnects, transistors) that have a second minimum size, where the second minimum size is greater than the first minimum size. In some implementations, the first and second dies 202(1), 202(2) may be fabricated using the same technology node or different technology nodes.

Note that the IC package 200 in FIG. 2A is not limited to including separate first and second dies 202(1), 202(2), and as chiplets. The IC package 200 could include a single monolithic die, such as a SoC for example. The IC package 200 could also be a multi-chip module (MCM) that includes IC chips or a flip chip ball grid array (FPBGA) that utilizes a controlled collapse chip connection technology, also known as flip chip, for die 202(1) or 202(2) to package substrate 206 interconnection.

The package substrate 206 may be a laminate type substrate that includes multiple metallization layers laminated to each other each with metal traces to provide signal routing paths. For example, the first and/or second electrical components 204(1), 204(2) may be electrically coupled to the first and/or second dies 202(1), 202(2) through signal routing paths in the package substrate 206. As another example, the package substrate 206 could be an embedded trace substrate (ETS) that includes embedded metal traces in an insulating layer of one or more metallization layers that are fabricated on top of each other with vias providing interconnections between the metal traces. The first and second electrical components 204(1), 204(2) are also coupled to the first side 214(1) of the package substrate 206 laterally adjacent to the respective first and second dies 202(1), 202(2) in the first, horizontal direction (X-axis and/or Y-axis directions). The stiffener structure 208 is also coupled to the first side 214(1) of the package substrate 206 to add stiffness to the package substrate 206. For example, the stiffener structure 208 may be a metal frame. An adhesive material 218 may be disposed between a first, outer surface 222 of the stiffener structure 208 and the first side 214(1) of the package substrate 206 to secure the stiffener structure 208 to the package substrate 206. In this manner, the first, outer surface 222 of the stiffener structure 208 is still coupled to the first side 214(1) of the package substrate 206, but not directly in contact with the first side 214(1) of the package substrate 206. The stiffener structure 208 could also be made from a non-metal material that has an increased stiffness to add stiffness to the package substrate 206. The stiffener structure 208 is disposed on the first side 214(1) of the package substrate 206 also adjacent to the first and second dies 202(1), 202(2).

As shown in FIG. 2A, the stiffener structure 208 includes the first and second cavities 212(1), 212(2) that encompass the respective electrical components 204(1), 204(2). The electrical components 204(1), 204(2) can be any type of electrical component, including a passive electrical component (e.g., a resistor, capacitor, inductor), or active electrical component that is powered. In this example, the electrical components 204(1), 204(2) are fully embedded in the cavities 212(1), 212(2) between respective upper surfaces 220(1), 220(2) of the stiffener structure 208 and the first side 214(1) of the package substrate 206. Note that in other examples discussed below, the electrical components 204(1), 204(2) are partially embedded in the cavities 212(1), 212(2). The upper surfaces 220(1), 220(2) are formed between the first, outer surface 222 of the stiffener structure 208 and a second, outer surface 224 of the stiffener structure 208. The first and second cavities 212(1), 212(2) are formed from a void of material in a portion of the stiffener structure 208 between the first, outer surface 222 and between a first, outer side wall 226(1) and a second, outer side wall 226(2) of the stiffener structure 208 in the first, horizontal direction (X-axis and/or Y-axis directions). The first and second cavities 212(1), 212(2) extend down to or adjacent to the second, outer surface 224 such that the first and second cavities 212(1), 212(2) have respective openings 228(1), 228(2) open to the first, outer surface 222 of the stiffener structure 208. In this manner, the first and second cavities 212(1), 212(2) are closed cavities closed in by the respective first and second upper surfaces 220(1), 220(2) of the stiffener structure 208. The openings 228(1), 228(2) of the first and second cavities 212(1), 212(2) extend down to or adjacent to the first side 214(1) of the package substrate 206 with the stiffener structure 208 mounted to the first side 214(1) of the package substrate 206.

Further, as shown in FIGS. 2A and 2B, an underfill material 230 is disposed adjacent to and underneath the first and second dies 202(1), 202(2) to reinforce the stability of the first and second dies 202(1), 202(2) and their solder joints 232(1), 232(2) to the package substrate 206. Another non-limiting benefit of providing the cavities 212(1), 212(2) in the stiffener structure 208 to encompass the first and second electrical components 204(1), 204(2) is that the stiffener structure 208 provides an underfill shield or dam between the underfill material 230 and the first and second electrical components 204(1), 204(2). In this example, by the stiffener structure 208 being located adjacent to the first and second dies 202(1), 202(2) in the first, horizontal direction (X-axis and/or Y-axis directions), the first, outer side wall 226(1) of stiffener structure 208 located adjacent to the first and second dies 202(1), 202(2) in the first, horizontal direction (X-axis and/or Y-axis directions) can act as an underfill shield or dam. If the stiffener structure 208 is coupled to the package substrate 206 before the underfill material 230 is disposed around and underneath the first and second dies 202(1), 202(2), the first, outer side wall 226(1) provides a shield or dam to prevent the underfill material 230 from reaching and contacting the first and second electrical components 204(1), 204(2). The underfill material 230 is permitted to contact the first, outer side wall 226(1) without issue since the stiffener structure 208 does not provide electrical functionality in the IC package 200. In this manner, any keep-out-zones KoZ₃, KoZ₄ that are provided between the respective first and second dies 202(1), 202(2) and the stiffener structure 208 may be able to be reduced in width in the first, horizontal direction (X-axis and/or Y-axis directions). This allows first and second distances D₁, D₂ of the first and second electrical components 204(1), 204(2) to respective side walls 234(1), 234(2) of the first and second dies 202(1), 202(2) in the first, horizontal direction (X-axis and/or Y-axis directions) to be reduced, which also allows the width W₁ of the package substrate 206 to be reduced while still being able to support the first and second electrical components 204(1), 204(2) and the stiffener structure 208. For example, the first second distances D₁, D₂ may be between 0.65 to 1.2 millimeters (mm).

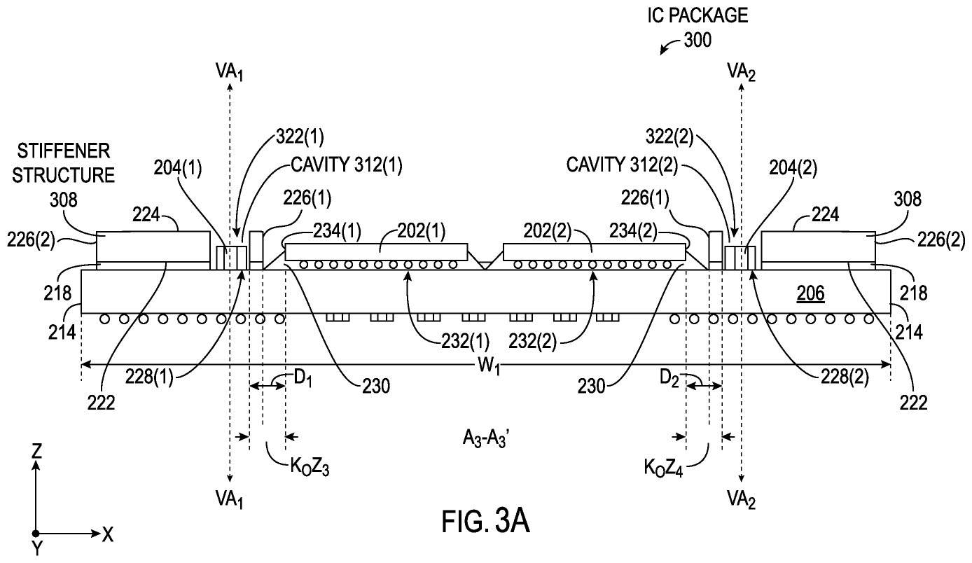

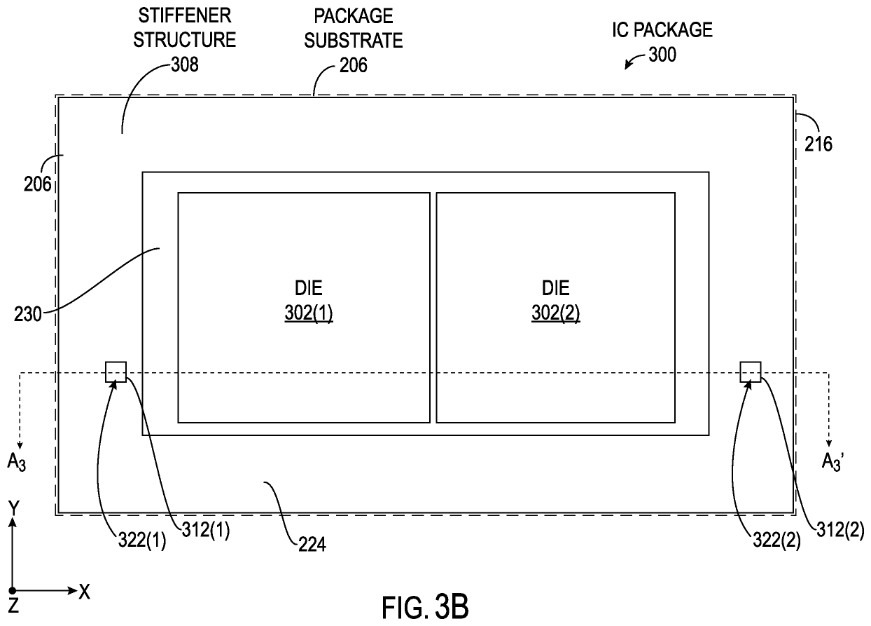

As discussed in FIGS. 2A and 2B above, the IC package 200 therein includes the stiffener structure 208 that has closed cavities 212(1), 212(2) that are bounded by the respective first and second upper surfaces 220(1), 220(2) of the stiffener structure 208. However, such is not required. Cavities provided in a stiffener structure to encompass an electrical component could be provided as open cavities that allow the electrical component to be exposed in the second, vertical direction (Z-axis direction) from its cavity, and thus partially encompassed by the cavity. This is shown in the exemplary IC package 300 in FIGS. 3A and 3B as another example. FIGS. 3A and 3B are respective side and top views of an exemplary IC package 300 that includes an alternative stiffener structure 308 that is like the stiffener structure 208 in the IC package 200 in FIGS. 2A and 2B. Common elements between the IC package 300 in FIGS. 3A and 3B and the IC package 200 in FIGS. 2A and 2B are shown with common element numbers and thus are not re-described. However, as shown in FIGS. 3A and 3B, the stiffener structure 308 in the IC package 300 includes first and second cavities 312(1), 312(2) that are not bounded by first and second upper surfaces 220(1), 220(2), and thus have openings 322(1), 322(2) in the second, outer surface 224.

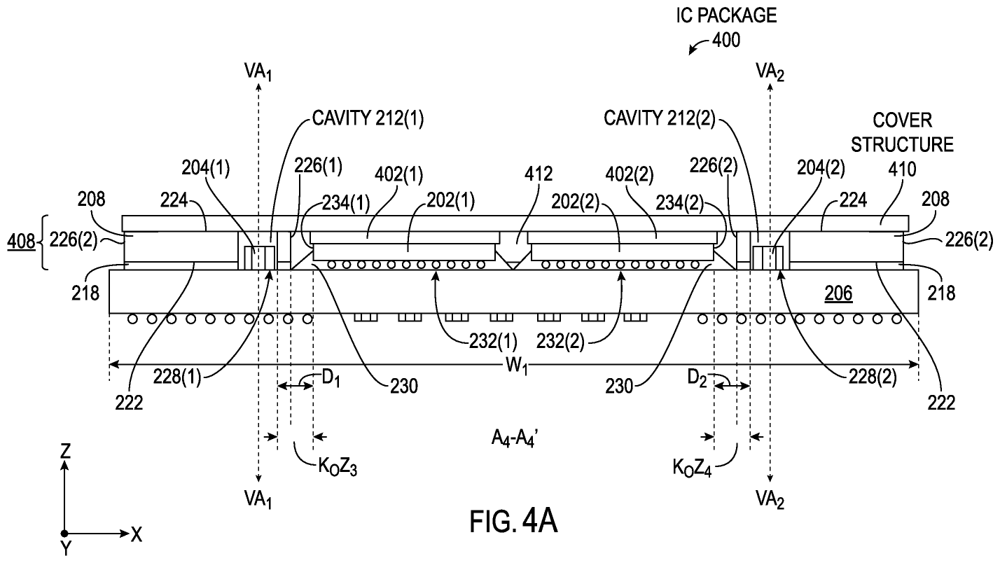

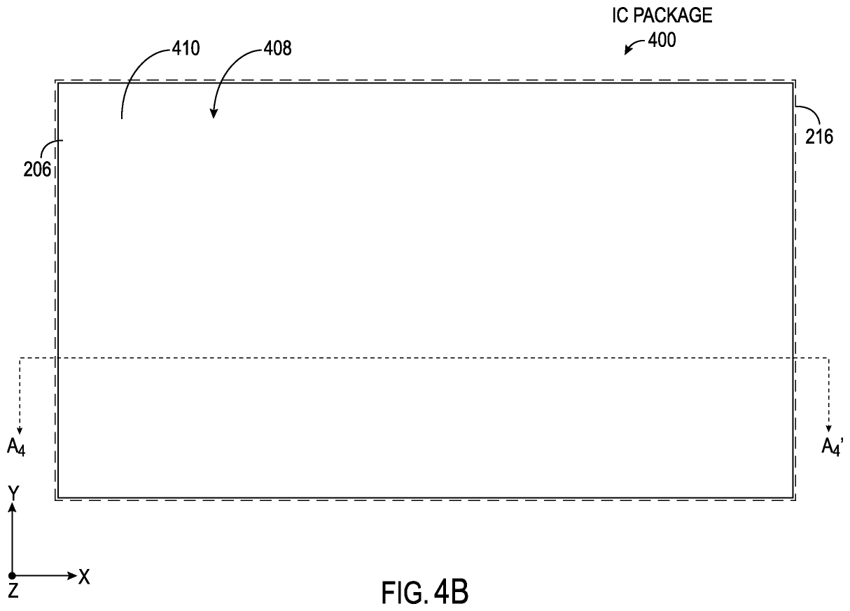

The stiffener structure provided in an IC package, like the IC packages 200, 300 in FIGS. 2A-3B can also dissipate heat and/or be part of a heat spreader to dissipate heat. In this regard, FIGS. 4A and 4B are respective side and top views of another exemplary IC package 400 that includes a stiffener structure 208 that is like the stiffener structure 208 in the IC package 200 in FIGS. 2A-2B. Common elements between the IC package 400 in FIGS. 4A-4B and the IC package 200 in FIGS. 2A-2B are shown with common element numbers, and thus are not re-described. However, as shown in FIGS. 4A and 4B, a heat spreader structure 408 is provided that includes the stiffener structure 208 and a cover structure 410. An optional thermal transfer material 402(1), 402(2) (e.g. a thermal paste, thermal grease) is disposed on the first and second dies 202(1), 202(2) to prepare for the cover structure 410 to be disposed thereon to facilitate heat transfer from the first and second dies 202(1), 202(2) to the cover structure 410. The cover structure 410 in this example, is a separate component, which may be a metal component, and is coupled to the second, outer surface 224 of the stiffener structure 208 to close off a cavity 412 between the dies 202(1), 202(2) as shown in FIG. 4B. The cover structure 410 extends in the first, horizontal direction (X-axis and Y-axis directions) along the second, outer surface 224 of the stiffener structure 208 such that the cover structure 410 intersects the first and second dies 202(1), 202(2) in the second, vertical direction (Z-axis direction). In this manner, the cover structure 410 is adjacent to the first and second dies 202(1), 202(2) to assist in dissipation of heat generated by the first and second dies 202(1), 202(2).

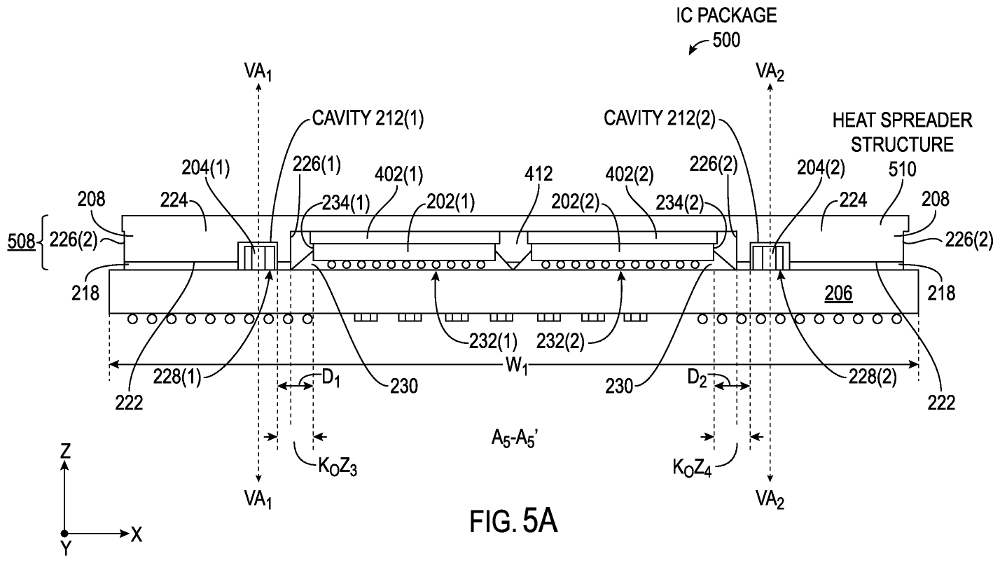

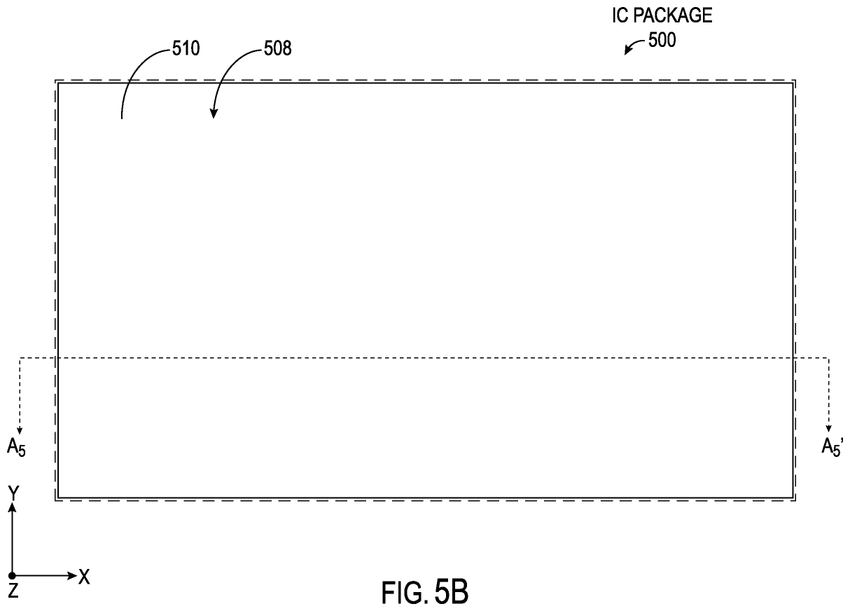

FIGS. 5A and 5B are respective side and top views of another exemplary IC package 500 that includes a heat spreader structure 508 that is like the heat spreader structure 408 in the IC package 400 in FIGS. 4A-4B. Common elements between the IC package 500 in FIGS. 5A-5B and the IC package 400 in FIGS. 4A-4B are shown with common element numbers, and thus are not re-described. However, as shown in FIGS. 5A and 5B, the heat spreader structure 508 is provided that includes the stiffener structure 208 and a cover structure 510 as a single monolithic component. For example, the heat spreader structure 508 may have been fabricated from a mold as a one-piece component. The heat spreader structure 508 be a metal component, and is coupled to the first side 214(1) of the package substrate 206. The cover structure 510 extends in the first, horizontal direction (X-axis and Y-axis directions) such that the cover structure 510 intersects the first and second dies 202(1), 202(2) in the second, vertical direction (Z-axis direction). In this manner, the cover structure 510 is adjacent to the first and second dies 202(1), 202(2) to assist in dissipation of heat generated by the first and second dies 202(1), 202(2).

Note that with the stiffener structure 208 being provided as a monolithic part of the heat spreader structure 508 in the IC package 500 in FIGS. 5A and 5B, the cavity 412 is not accessible to dispose the underfill material 230 around the dies 202(1), 202(2) once the heat spreader structure 508 with its stiffener structure 208 is coupled to the package substrate 206.

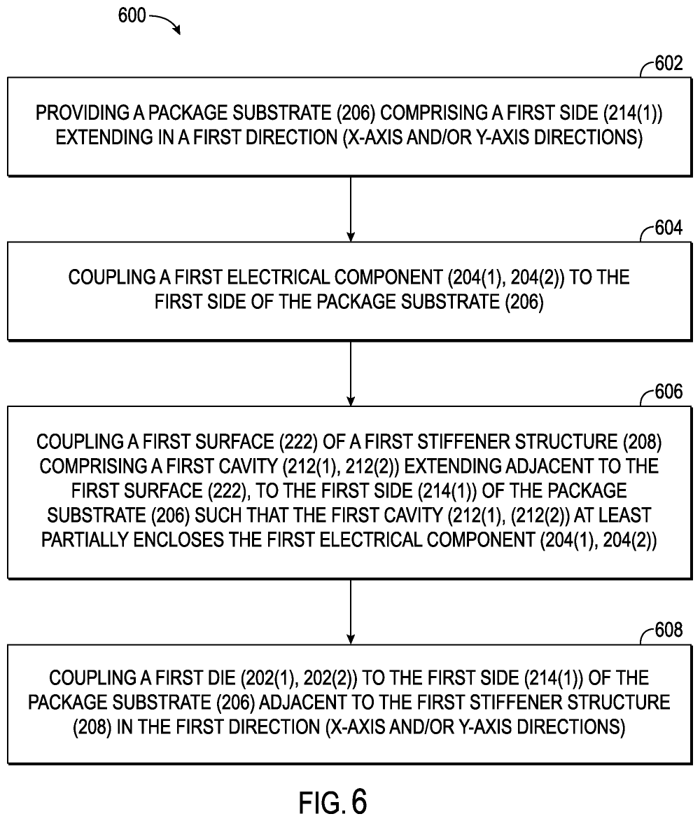

FIG. 6 is a flowchart illustrating an exemplary process of fabricating an IC package that includes a stiffener structure coupled to a first side of a package substrate to increase stiffness of the IC package, and wherein the stiffener structure includes an integrated cavity(ies) extending to the first side of the package substrate and encompassing an electrical component(s) coupled to the first side of the package substrate, including, but not limited to, the IC packages 200, 300, 400, 500 in FIGS. 2A-5B. The fabrication process 600 is discussed in reference to the IC package 200 in FIGS. 2A-2B, but the fabrication process 600 is not limited to fabricating the IC package 200 in FIGS. 2A-2B.

In this regard, a first step in the fabrication process 600 is providing a package substrate 206 comprising a first side 214(1) extending in a first direction (X-axis and/or Y-axis directions) (block 602 in FIG. 6). A next step in the fabrication process 600 is coupling a first electrical component 204(1), 204(2) to the first side 214(1) of the package substrate 206 (block 604 in FIG. 6). A next step in the fabrication process 600 is coupling a first surface 222 of a first stiffener structure 208 comprising a first cavity 212(1), 212(2) extending adjacent to first surface 222, to the first side 214(1) of the package substrate 206 such that the first cavity 212(1), 212(2) at least partially encloses the first electrical component 204(1), 204(2) (block 606 in FIG. 6). A next step in the fabrication process 600 is coupling a first die 202(1), 202(2) to the first side 214(1) of the package substrate 206 adjacent to the first stiffener structure 208 in the first direction (X-axis and/or Y-axis directions) (block 608 in FIG. 6).

An IC package that includes a stiffener structure coupled to a first side of a package substrate to increase stiffness of the IC package, and wherein the stiffener structure includes an integrated cavity(ies) extending to the first side of the package substrate and encompassing an electrical component(s) coupled to the first side of the package substrate, including, but not limited to, the IC packages 200, 300, 400, 500 in FIGS. 2A-5B, can be fabricated in other fabrication processes.

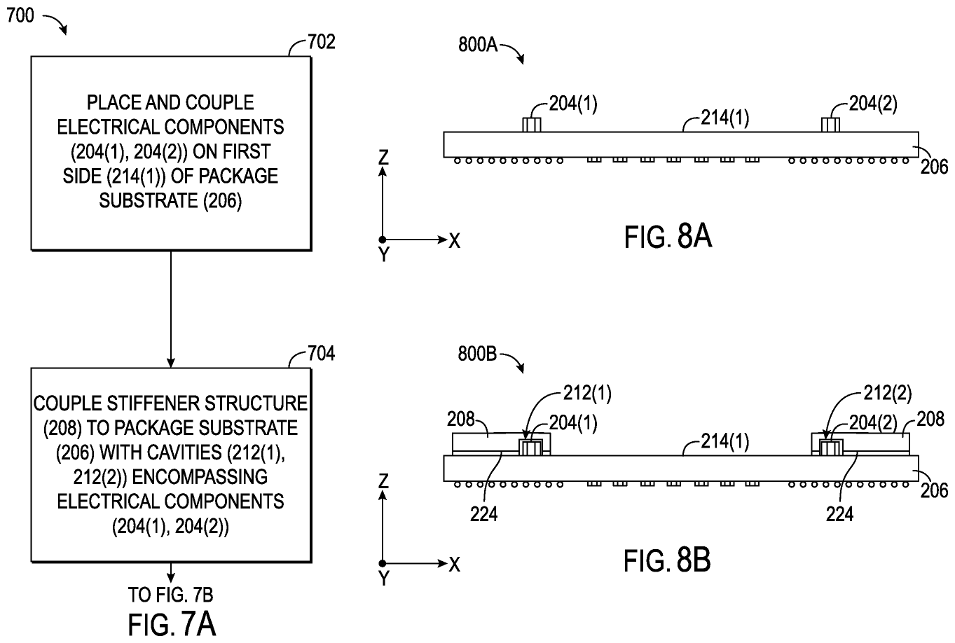

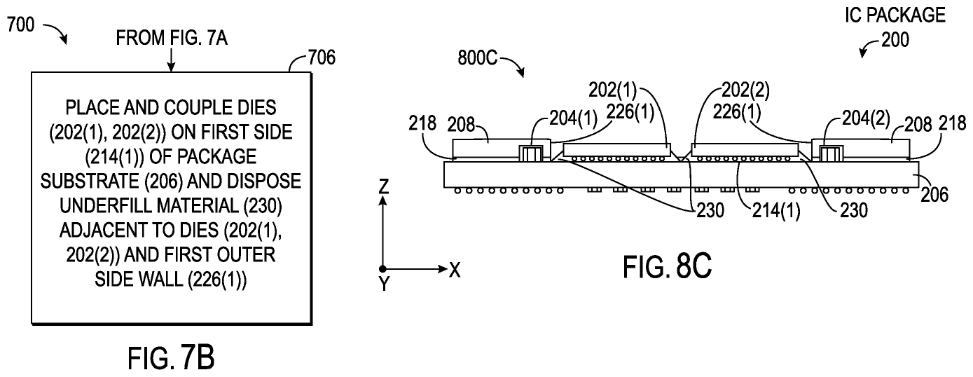

For example, FIGS. 7A and 7B is a flowchart illustrating an exemplary fabrication process 700 of fabricating the IC package 200 in FIGS. 2A-2B that includes the stiffener structure 208 coupled to the first side 214(1) of the package substrate 206 to increase stiffness of the IC package 200, and wherein the stiffener structure 208 includes an integrated cavity(ies) 212(1), 212(2) extending to the first side 214(1) of the package substrate 206 and encompassing an electrical component(s) 204(1), 204(2) coupled to the first side 214(1) of the package substrate 206. FIGS. 8A-8C illustrate exemplary fabrication stages 800A-800C during fabrication of the IC package 200 according to the fabrication process 700 in FIGS. 7A and 7B. The fabrication process 700 in FIGS. 7A and 7B is discussed below with reference to the fabrication stages 800A-800C in FIGS. 8A-8C.

In this regard, as illustrated in fabrication stage 800A in FIG. 8A, the fabrication process 700 includes providing the package substrate 206 and coupling the electrical components 204(1), 204(2) to the first side 214(1) of the package substrate 206 (block 702 in FIG. 7A). Then, as illustrated in fabrication stage 800B in FIG. 8B, the fabrication process 700 includes coupling the stiffener structure 208 on the first side 214(1) of the package substrate 206 such that the cavities 212(1), 212(2) of the stiffener structure 208 are aligned with the electrical components 204(1), 204(2) and encompass the electrical components 204(1), 204(2) (block 704 in FIG. 7A). As previously discussed, an optional adhesive material 218 may be first disposed on the first side 214(1) of the package substrate 206 or on the second, outer surface 224 of the stiffener structure 208 to secure the stiffener structure 208 to the package substrate 206. Then, as illustrated in fabrication stage 800C in FIG. 8C, the fabrication process 700 includes placing and coupling the first and second dies 202(1), 202(2) to the first side 214(1) of the package substrate 206 and disposing the underfill material 230 adjacent to and underneath the dies 202(1), 202(2) to form the IC package 200 (block 706 in FIG. 7B). Note that as discussed previously, with the stiffener structure 208 coupled to the package substrate 206 before the underfill material 230 is disposed around the dies 202(1), 202(2), the first, outer side wall 226(1) of the stiffener structure 208 acts as a shield or dam to prevent the underfill material 230 from interfering with the first and second electrical components 204(1), 204(2).

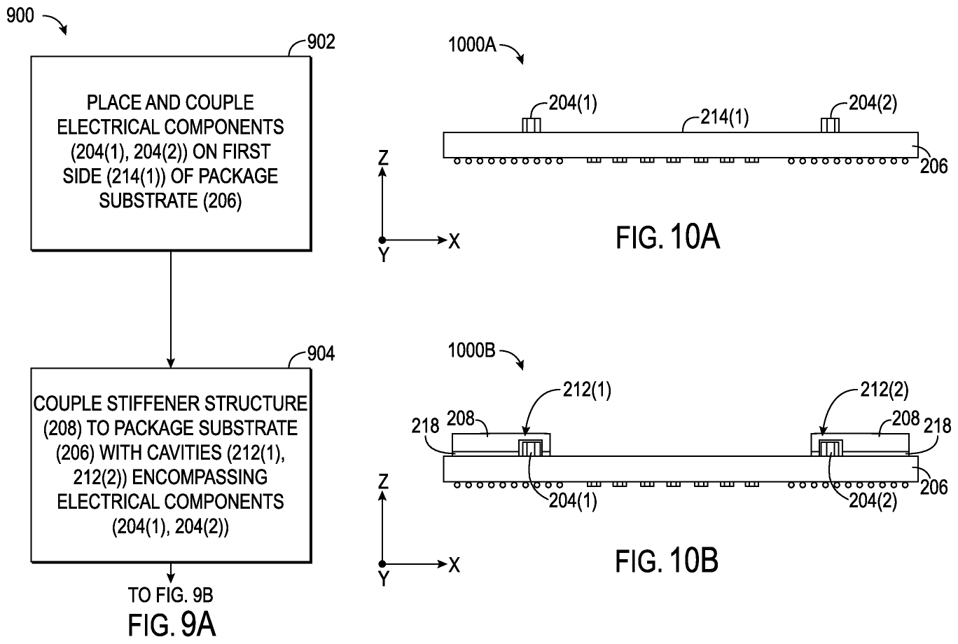

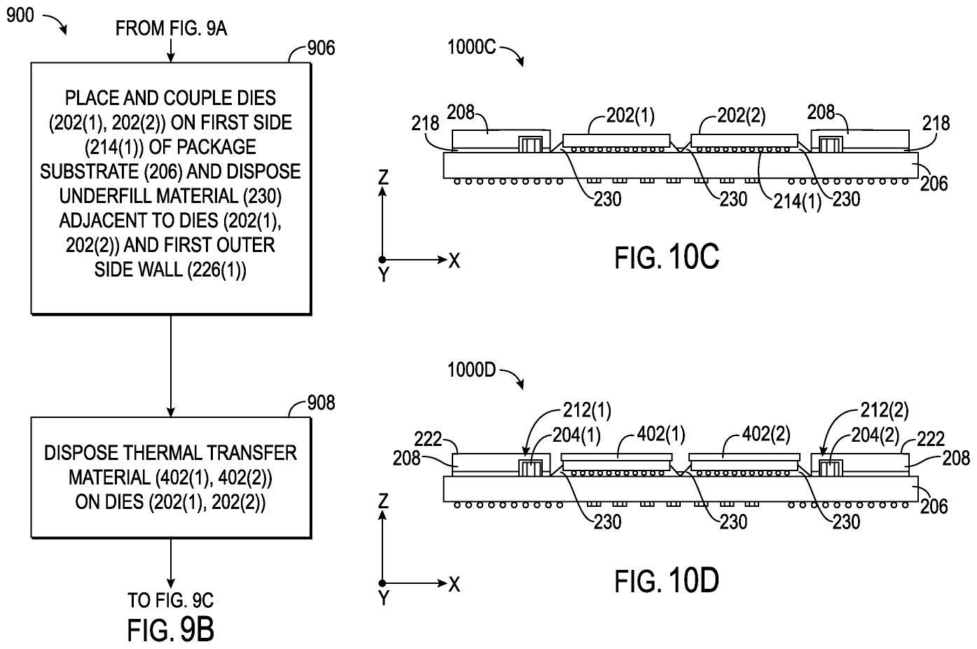

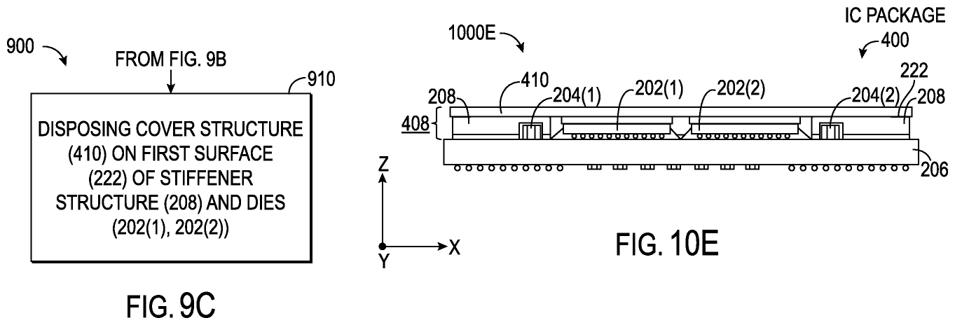

FIGS. 9A-9C is a flowchart illustrating an exemplary fabrication process 900 of fabricating the IC package 400 in FIGS. 4A-4B that includes the stiffener structure 208 that is included in a heat spreader structure 408. FIGS. 10A-10E illustrate exemplary fabrication stages 1000A-1000E during fabrication of the IC package 400 according to the fabrication process 900 in FIGS. 9A-9C. The fabrication process 900 in FIGS. 9A-9C is discussed below with reference to the fabrication stages 1000A-1000E in FIGS. 10A-10E.

In this regard, the first three fabrication stages 1000A-1000C in FIGS. 10A-10C of the fabrication process 900 and their related process steps 902, 904, 906 in FIGS. 9A and 9B are the same as the first three fabrication stages 800A-800C in FIGS. 8A-8C of the fabrication process 700 in FIGS. 7A-7B, and thus will not be repeated. As discussed previously, with the stiffener structure 208 coupled to the package substrate 206 before the underfill material 230 is disposed around the dies 202(1), 202(2), the first, outer side wall 226(1) of the stiffener structure 208 acts as a shield or dam to prevent the underfill material 230 from interfering with the first and second electrical components 204(1), 204(2). Then, as illustrated in fabrication stage 1000D in FIG. 10D, the fabrication process 900 includes providing an optional thermal transfer material 402(1), 402(2) (e.g. a thermal paste, thermal grease) on the first and second dies 202(1), 202(2) to prepare for the cover structure 410 to be disposed thereon and on the first surface 222 of the stiffener structure 208 (block 908 in FIG. 9B). The thermal transfer material 402(1), 402(2) will provide a good thermal transfer between the dies 202(1), 202(2) and the cover structure 410 of the heat spreader structure 408 to efficiently dissipate heat. Then, as illustrated in fabrication stage 1000E in FIG. 10E, the fabrication process 900 includes disposing the cover structure 410 on the first surface 222 of the stiffener structure 208 and on the thermal transfer material 402(1), 402(2) adjacent to the first and second dies 202(1), 202(2) to form the IC package 400 (block 910 in FIG. 9C).

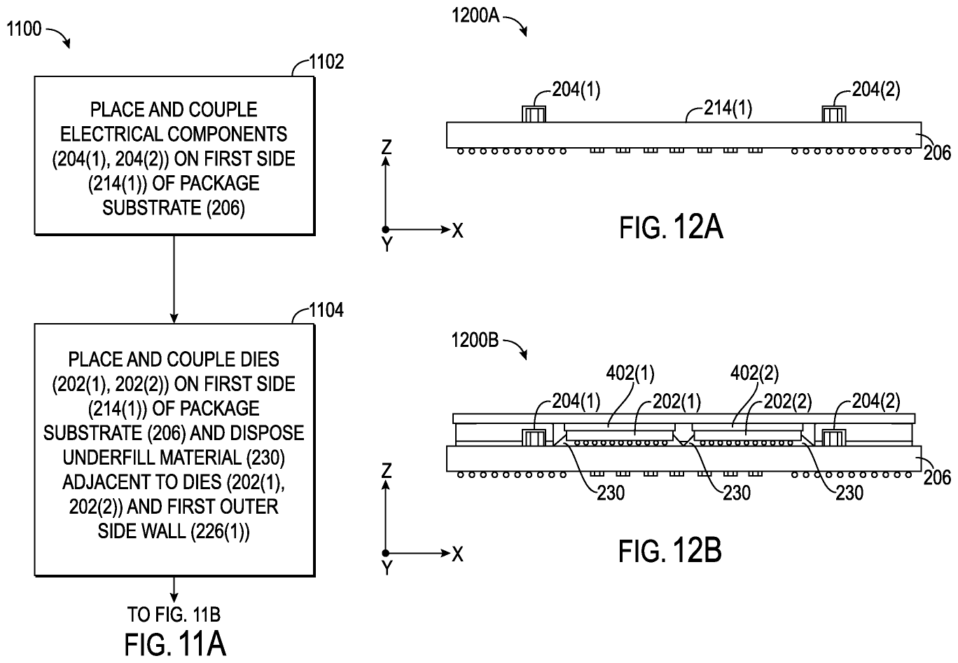

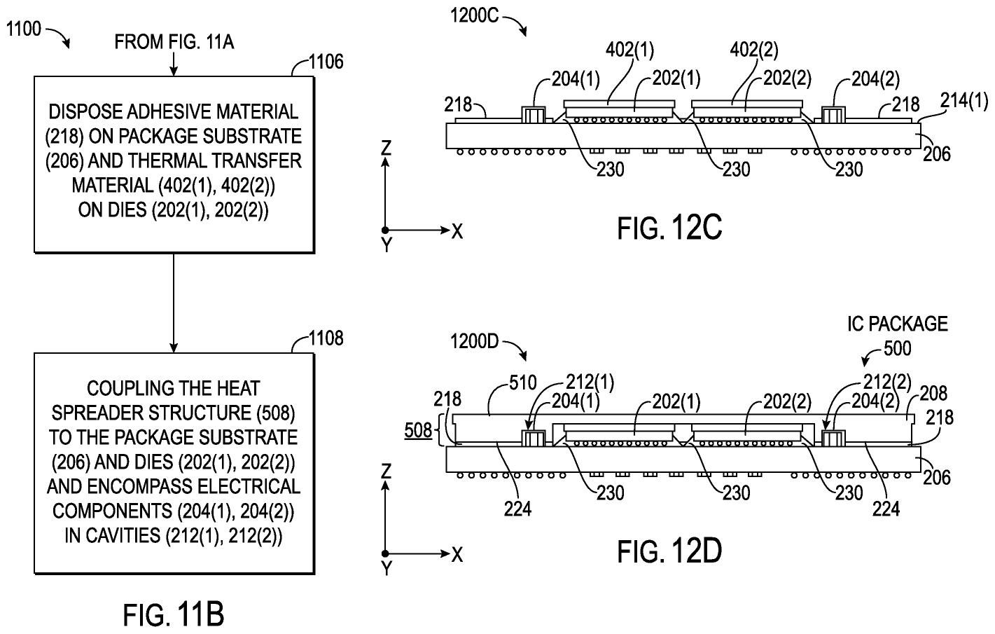

FIGS. 11A-11B is a flowchart illustrating the exemplary fabrication process 1100 of fabricating the IC package 500 in FIGS. 5A-5B that includes the stiffener structure 208 in a heat spreader structure 508 as a monolithic structure. FIGS. 12A-12D illustrate exemplary fabrication stages 1200A-1200D during fabrication of the IC package 500 according to the fabrication process 1100 in FIGS. 11A-11B. The fabrication process 1100 in FIGS. 11A-11B is discussed below with reference to the fabrication stages 1200A-1200D in FIGS. 12A-12D.

In this regard, the first fabrication stage 1200A in FIG. 12A of the fabrication process 1100 and its process step 1102 in FIG. 11A is the same as the fabrication stage 800A in FIG. 8A of the fabrication process 700 in FIGS. 7A-7B, and thus will not be repeated.

As illustrated in fabrication stage 1200B in FIG. 12B, the fabrication process 1100 then includes placing and coupling the first and second dies 202(1), 202(2) to the first side 214(1) of the package substrate 206 and disposing the underfill material 230 adjacent to and underneath the dies 202(1), 202(2) to form the IC package 500 (block 1104 in FIG. 11A). Note that in this example, because the stiffener structure 208 is part of a monolithic structure of the heat spreader structure 508, the dies 202(1), 202(2) are coupled to the package substrate 206 before the heat spreader structure 508 is placed and coupled to the package substrate 206 with its cavities 212(1), 212(2) encompassing the first and second electrical components 204(1), 204(2). This is because the cover structure 510 of the heat spreader structure 508, if coupled to the package substrate 206 before the dies 202(1), 202(2), would block access for the dies 202(1), 202(2) to be coupled to the package substrate 206 and the underfill material 230 disposed around the dies 202(1), 202(2). Thus, in this example, the stiffener structure 208 cannot act as an underfill shield or dam from the underfill material 230.

Then, as illustrated in fabrication stage 1200C in FIG. 12C, the fabrication process 1100 includes disposing the adhesive material 218 on the first side 214(1) of the package substrate 206 where the second surface 224 of the stiffener structure 208 will be coupled, and disposing the thermal transfer material 402(1), 402(2) on the first and second dies 202(1), 202(2) (block 1106 in FIG. 11B). This is to prepare the package substrate 206 to receive and be coupled to the heat spreader structure 508. Then, as illustrated in fabrication stage 1200D in FIG. 12D, the fabrication process 1100 includes coupling the heat spreader structure 508 on the package substrate 206 such that second surface 224 of the stiffener structure 208 is coupled to the adhesive material 218 on the first side 214(1) of the package substrate 206 and the cover structure 510 is coupled to the thermal transfer material 402(1), 402(2) with the first and second electrical components 204(1), 204(2) encompassed in the first and second cavities 212(1), 212(2) of the stiffener structure 208 to form the IC package 500 (block 1108 in FIG. 11D). In this regard, the heat spreader structure 508 is coupled to the package substrate 206 to add stiffness to the package substrate 206 while also providing a heat sink to dissipate heat generated by the first and second dies 202(1), 202(2).

It should be understood that the terms “first,” “second,” “third,” etc., where used herein, are relative terms and are not meant to limit or imply a strict orientation. It should also be understood that that the terms “top,” “upper,” “above,” and “bottom,” “lower,” “below,” where used herein, are relative terms and are not meant to limit or imply a strict orientation. A “top” or “upper” or “above” referenced element does not always need to be oriented to be above a “bottom,” or “lower,” or “below” referenced element with respect to ground, and vice versa. An element referenced as “top,” “upper,” “above,” or “bottom,” “lower,” “below,” may be on top or bottom relative to that example only and the particular illustrated example. An element referenced as “top” or “upper” or “above” “bottom,” “lower,” “below,” another element does not have to be with respect to ground, and vice versa. An element referenced as “top” or “upper” or “above” may be above or below such other referenced element, relative to that example only and the particular illustrated example.

Further, an object being “adjacent” as discussed herein relates to an object being beside or next to another stated object. Adjacent objects may not be directly physically coupled to each other. An object can be directly adjacent to another object which means that such objects are directly beside or next to the other object without another object or layer being intervening or disposed between the directly adjacent objects. An object can be indirectly or non-directly adjacent to another object which means that such objects are not directly beside or directly next to each other, but there is an intervening object or layer disposed between the non-directly adjacent objects.

IC packages that include a stiffener structure coupled to a first side of a package substrate to increase stiffness of the IC package, and wherein the stiffener structure includes an integrated cavity(ies) extending to the first side of the package substrate and encompassing an electrical component(s) coupled to the first side of the package substrate, including, but not limited to, the IC packages 200, 300, 400, 500 in FIGS. 2A-5B, and that can be fabricated according to any fabrication process, including, but not limited to, the fabrication processes 600, 700, 900, 1100 in FIGS. 6, 7A-7B, 9A-9C, and 11A-11B, and according to any aspects disclosed herein, may be provided in or integrated into any processor-based device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

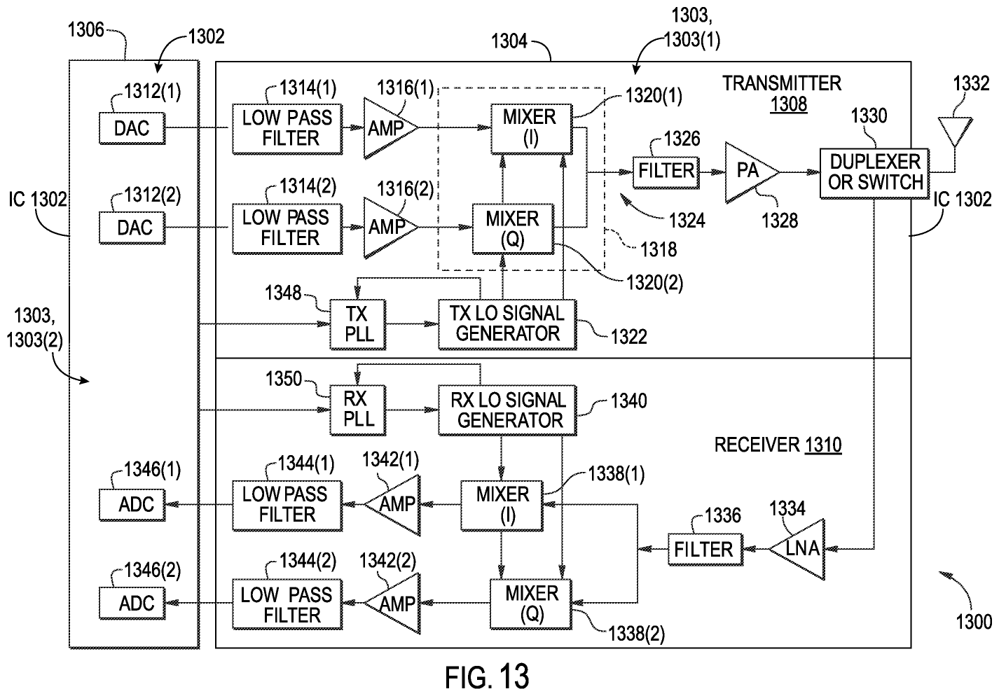

In this regard, FIG. 13 illustrates an exemplary wireless communications device 1300 that includes electrical components formed from one or more ICs 1302, wherein any of the ICs 1302 can be included in an IC package 1303, 1303(1), 1303(2). The IC packages 1303, 1303(1), 1303(2) can include a stiffener structure coupled to a first side of a package substrate to increase stiffness of the IC package, and wherein the stiffener structure includes an integrated cavity(ies) extending to the first side of the package substrate and encompassing an electrical component(s) coupled to the first side of the package substrate, including, but not limited to, the IC packages 200, 300, 400, 500 in FIGS. 2A-5B, ad that can be fabricated according to any fabrication process, including, but not limited to, the fabrication processes 600, 700, 900, 1100 in FIGS. 6, 7A-7B, 9A-9C, and 11A-11B, and according to any aspects disclosed herein. The wireless communications device 1300 may include or be provided in any of the above referenced devices, as examples. As shown in FIG. 13, the wireless communications device 1300 includes a transceiver 1304 and a data processor 1306. The data processor 1306 may include a memory to store data and program codes. The transceiver 1304 includes a transmitter 1308 and a receiver 1310 that support bi-directional communications. In general, the wireless communications device 1300 may include any number of transmitters 1308 and/or receivers 1310 for any number of communication systems and frequency bands. All or a portion of the transceiver 1304 may be implemented on one or more analog ICs, RF ICs (RFICs), mixed-signal ICs, etc.

The transmitter 1308 or the receiver 1310 may be implemented with a super-heterodyne architecture or a direct-conversion architecture. In the super-heterodyne architecture, a signal is frequency-converted between RF and baseband in multiple stages, e.g., from RF to an intermediate frequency (IF) in one stage, and then from IF to baseband in another stage for the receiver 1310. In the direct-conversion architecture, a signal is frequency-converted between RF and baseband in one stage. The super-heterodyne and direct-conversion architectures may use different circuit blocks and/or have different requirements. In the wireless communications device 1300 in FIG. 13, the transmitter 1308 and the receiver 1310 are implemented with the direct-conversion architecture.

In the transmit path, the data processor 1306 processes data to be transmitted and provides I and Q analog output signals to the transmitter 1308. In the exemplary wireless communications device 1300, the data processor 1306 includes digital-to-analog converters (DACs) 1312(1), 1312(2) for converting digital signals generated by the data processor 1306 into the I and Q analog output signals, e.g., I and Q output currents, for further processing.

Within the transmitter 1308, lowpass filters 1314(1), 1314(2) filter the I and Q analog output signals, respectively, to remove undesired signals caused by the prior digital-to-analog conversion. Amplifiers (AMPs) 1316(1), 1316(2) amplify the signals from the lowpass filters 1314(1), 1314(2), respectively, and provide I and Q baseband signals. An upconverter 1318 upconverts the I and Q baseband signals with I and Q transmit (TX) local oscillator (LO) signals through mixers 1320(1), 1320(2) from a TX LO signal generator 1322 to provide an upconverted signal 1324. A filter 1326 filters the upconverted signal 1324 to remove undesired signals caused by the frequency upconversion as well as noise in a receive frequency band. A power amplifier (PA) 1328 amplifies the upconverted signal 1324 from the filter 1326 to obtain the desired output power level and provides a transmit RF signal. The transmit RF signal is routed through a duplexer or switch 1330 and transmitted via an antenna 1332.

In the receive path, the antenna 1332 receives signals transmitted by base stations and provides a received RF signal, which is routed through the duplexer or switch 1330 and provided to a low noise amplifier (LNA) 1334. The duplexer or switch 1330 is designed to operate with a specific receive (RX)-to-TX duplexer frequency separation, such that RX signals are isolated from TX signals. The received RF signal is amplified by the LNA 1334 and filtered by a filter 1336 to obtain a desired RF input signal. Downconversion mixers 1338(1), 1338(2) mix the output of the filter 1336 with I and Q RX LO signals (i.e., LO_I and LO_Q) from an RX LO signal generator 1340 to generate I and Q baseband signals. The I and Q baseband signals are amplified by AMPs 1342(1), 1342(2) and further filtered by lowpass filters 1344(1), 1344(2) to obtain I and Q analog input signals, which are provided to the data processor 1306. In this example, the data processor 1306 includes analog-to-digital converters (ADCs) 1346(1), 1346(2) for converting the analog input signals into digital signals to be further processed by the data processor 1306.

In the wireless communications device 1300 of FIG. 13, the TX LO signal generator 1322 generates the I and Q TX LO signals used for frequency upconversion, while the RX LO signal generator 1340 generates the I and Q RX LO signals used for frequency downconversion. Each LO signal is a periodic signal with a particular fundamental frequency. A TX phase-locked loop (PLL) circuit 1348 receives timing information from the data processor 1306 and generates a control signal used to adjust the frequency and/or phase of the TX LO signals from the TX LO signal generator 1322. Similarly, an RX PLL circuit 1350 receives timing information from the data processor 1306 and generates a control signal used to adjust the frequency and/or phase of the RX LO signals from the RX LO signal generator 1340.

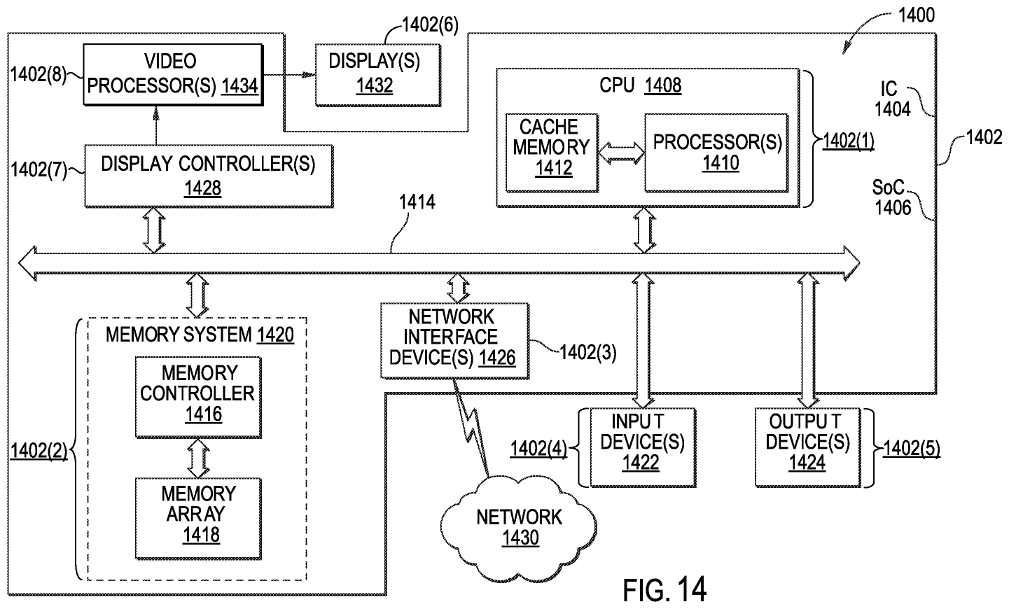

FIG. 14 illustrates an example of a processor-based system 1400 that can include one or more IC packages 1402, 1402(1)-1402(8) that include a stiffener structure coupled to a first side of a package substrate to increase stiffness of the IC package, and wherein the stiffener structure includes an integrated cavity(ies) extending to the first side of the package substrate and encompassing an electrical component(s) coupled to the first side of the package substrate, including, but not limited to, the IC packages 200, 300, 400, 500 in FIGS. 2A-5B, ad that can be fabricated according to any fabrication process, including, but not limited to, the fabrication processes 600, 700, 900, 1100 in FIGS. 6, 7A-7B, 9A-9C, and 11A-11B, and according to any aspects disclosed herein.

In this example, the processor-based system 1400 may be formed as an IC 1404 in an IC package 1402 and as a system-on-a-chip (SoC) 1406. In this example, the processor-based system 1400 may be provided as or include a system-on-a-chip (SoC) 1406. The processor-based system 1400 includes a CPU 1408 that includes one or more processors 1410, which may also be referred to as CPU cores or processor cores. The CPU 1408 can be included in an IC package 1402(1). The CPU 1408 may have cache memory 1412 coupled to the CPU 1408 for rapid access to temporarily stored data. The CPU 1408 is coupled to a system bus 1414 and can intercouple master and slave devices included in the processor-based system 1400. As is well known, the CPU 1408 communicates with these other devices by exchanging address, control, and data information over the system bus 1414. For example, the CPU 1408 can communicate bus transaction requests to a memory controller 1416 as an example of a slave device. Although not illustrated in FIG. 14, multiple system buses 1414 could be provided, wherein each system bus 1414 constitutes a different fabric.

Other master and slave devices can be connected to the system bus 1414. As illustrated in FIG. 14, these devices can include a memory system 1420 that includes the memory controller 1416 and a memory array(s) 1418, one or more input devices 1422, one or more output devices 1424, one or more network interface devices 1426, and one or more display controllers 1428, as examples. The memory system 1420 can be included in an IC package 1402(2). The network interface devices 1426 can be included in an IC package 1402(3). Each of the memory system 1420, the one or more input devices 1422, the one or more output devices 1424, the one or more network interface devices 1426, and the one or more display controllers 1428 can be provided in the same or different circuit packages. The input devices 1422 and/or the output devices 1424 can be included in respective IC packages 1402(4), 1402(5) to dissipate heat. The input device(s) 1422 can include any type of input device, including, but not limited to, input keys, switches, voice processors, etc. The output device(s) 1424 can include any type of output device, including, but not limited to, audio, video, other visual indicators, etc. The network interface device(s) 1426 can be any device configured to allow exchange of data to and from a network 1430. The network 1430 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 1426 can be configured to support any type of communications protocol desired.

The CPU 1408 may also be configured to access the display controller(s) 1428 over the system bus 1414 to control information sent to one or more displays 1432. The display 1432 can be included in an IC package 1402(6) to dissipate heat. The display controller(s) 1428 sends information to the display(s) 1432 to be displayed via one or more video processors 1434, which process the information to be displayed into a format suitable for the display(s) 1432. The display controller(s) 1428 and video processor(s) 1434 can be included in respective IC packages 1402(7), 1402(8) or the same IC package, and/or in the same or different IC package 1402(1) containing the CPU 1408 as an example. The display(s) 1432 can include any type of display, including, but not limited to, a cathode ray tube (CRT), a liquid crystal display (LCD), a plasma display, a light emitting diode (LED) display, etc.

Those of skill in the art will further appreciate that the various illustrative logical blocks, modules, circuits, and algorithms described in connection with the aspects disclosed herein may be implemented as electronic hardware, instructions stored in memory or in another computer readable medium and executed by a processor or other processing device, or combinations of both. The master and slave devices described herein may be employed in any circuit, hardware component, IC, or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein, but is to be accorded the widest scope consistent with the principles and novel features disclosed herein.

Implementation examples are also described in the following numbered clauses:

1. An integrated circuit (IC) package, comprising:
a package substrate comprising a first side extending in a first direction;
a first die coupled to the first side of the package substrate;
a first stiffener structure adjacent to the first die in the first direction and coupled to the first side of the package substrate, the first stiffener structure comprising:
   a first cavity extending adjacent to the first side of the package substrate; and
a first electrical component coupled to the first side of the package substrate, the first electrical component at least partially embedded in the first cavity.
   2. The IC package of clause 1, wherein the first stiffener structure does not intersect the first die in a second direction orthogonal to the first direction.
   3. The IC package of clause 1 or 2, wherein the first cavity does not intersect the first die in a second direction orthogonal to the first direction.
   4. The IC package of any of clauses 1-3, wherein the first electrical component is fully embedded in the first cavity.
   5. The IC package of any of clauses 1-4, wherein the first stiffener structure further comprises:
a first surface adjacent to the package substrate; and
a second surface opposite the first surface in a second direction orthogonal to the first direction;
the first cavity extending through to the first surface of the first stiffener structure to extend adjacent to the first side of the package substrate.
   6. The IC package of any of clauses 1-5, wherein the first stiffener structure further comprises:
a first outer side wall adjacent to the first die; and
a second outer side wall opposite the first outer side wall in the first direction;
the first cavity between the first outer side wall and the second outer side wall in the first direction.
   7. The IC package of clause 6, further comprising an underfill material adjacent to the first side of the package substrate and the first die;
wherein the first outer side wall is adjacent to the underfill material.
   8. The IC package of clause 7, wherein the first outer side wall is in contact with the underfill material.
   9. The IC package of any of clauses 1-8, wherein the first electrical component is a first distance in a second direction orthogonal to the first direction between 0.65 and 1.2 millimeters (mm) from a side wall of the first die adjacent to the first stiffener structure.
   10. The IC package of clause 5, wherein the first cavity further extends to the second surface of the first stiffener structure.
   11. The IC package of any of clauses 1-10, wherein the first stiffener structure comprises a ring-shaped stiffener structure.
   12. The IC package of clause 11, wherein the ring-shaped stiffener structure is adjacent to a perimeter of the package substrate.
   13. The IC package of any of clauses 1-12, wherein:
the first stiffener structure further comprises a second cavity extending adjacent to the first side of the package substrate; and
further comprising:
   a second electrical component coupled to the first side of the package substrate, the second electrical component at least partially embedded in the second cavity.
      14. The IC package of clause 13, wherein the first cavity and the second cavity are part of a common cavity in the first stiffener structure.
      15. The IC package of any of clauses 1-14, further comprising:
a second stiffener structure outside the first die in the first direction and coupled to the first side of the package substrate, the second stiffener structure comprising:
   a second cavity extending adjacent to the first side of the package substrate; and
a second electrical component coupled to the first side of the package substrate, the second electrical component at least partially embedded in the second cavity.
   16. The IC package of any of clauses 1-15, wherein the first electrical component is electrically coupled to the first die through the package substrate.
   17. The IC package of any of clauses 1-16, further comprising a heat spreader structure comprising the first stiffener structure and a cover structure extending in the first direction adjacent to the first die and fully intersecting the first die in a second direction orthogonal to the first direction.
   18. The IC package of clause 17, wherein the first stiffener structure and the cover structure are a monolithic structure.
   19. The IC package of any of clauses 1-18,
wherein the first die comprises a first chiplet; and
further comprising a second chiplet coupled to the first side of the package substrate;
wherein:
   the first chiplet electrically coupled to the second chiplet through the package substrate; and
   the first stiffener structure is further adjacent to the second chiplet in the first direction.
      20. The IC package of any of clauses 1-19 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.
      21. A method of fabricating an integrated circuit (IC) package, comprising:
providing a package substrate comprising a first side extending in a first direction;
coupling a first electrical component to the first side of the package substrate;
coupling a first surface of a first stiffener structure comprising a first cavity extending adjacent to the first surface, to the first side of the package substrate such that the first cavity at least partially encloses the first electrical component; and
coupling a first die to the first side of the package substrate adjacent to the first stiffener structure in the first direction.
   22. The method of clause 21, wherein coupling the first surface of the first stiffener structure further comprises not intersecting the first stiffener structure with the first die in a second direction orthogonal to the first direction.
   23. The method of clause 21 or 22, wherein coupling the first surface of the first stiffener structure further comprises the first cavity not intersecting the first die in a second direction orthogonal to the first direction.
   24. The method of any of clauses 21-23, further comprising coupling a cover structure to the first stiffener structure extending in the first direction adjacent to the first die and fully intersecting the first die in a second direction orthogonal to the first direction.
   25. The method of any of clauses 21-24, further comprising coupling the first electrical component to the first side of the package substate prior to coupling the first surface of the first stiffener structure to the first side of the package substrate.
   26. The method of any of clauses 21-25, further comprising disposing an underfill material adjacent to the first die after coupling the first surface of the first stiffener structure to the first side of the package substrate.

What is claimed is:

1. An integrated circuit (IC) package, comprising:
a package substrate comprising a first side extending in a first direction;
a first die coupled to the first side of the package substrate;
a first stiffener structure adjacent to the first die in the first direction and coupled to the first side of the package substrate, the first stiffener structure comprising:
a first cavity extending adjacent to the first side of the package substrate; and
a first electrical component coupled to the first side of the package substrate, the first electrical component at least partially embedded in the first cavity.

2. The IC package of claim 1, wherein the first stiffener structure does not intersect the first die in a second direction orthogonal to the first direction.

3. The IC package of claim 1, wherein the first cavity does not intersect the first die in a second direction orthogonal to the first direction.

4. The IC package of claim 1, wherein the first electrical component is fully embedded in the first cavity.

5. The IC package of claim 1, wherein the first stiffener structure further comprises:
a first surface adjacent to the package substrate; and
a second surface opposite the first surface in a second direction orthogonal to the first direction;
the first cavity extending through to the first surface of the first stiffener structure to extend adjacent to the first side of the package substrate.

6. The IC package of claim 1, wherein the first stiffener structure further comprises:
a first outer side wall adjacent to the first die; and
a second outer side wall opposite the first outer side wall in the first direction;
the first cavity between the first outer side wall and the second outer side wall in the first direction.

7. The IC package of claim 6, further comprising an underfill material adjacent to the first side of the package substrate and the first die;
wherein the first outer side wall is adjacent to the underfill material.

8. The IC package of claim 7, wherein the first outer side wall is in contact with the underfill material.

9. The IC package of claim 1, wherein the first electrical component is a first distance in a second direction orthogonal to the first direction between 0.65 and 1.2 millimeters (mm) from a side wall of the first die adjacent to the first stiffener structure.

10. The IC package of claim 5, wherein the first cavity further extends to the second surface of the first stiffener structure.

11. The IC package of claim 1, wherein the first stiffener structure comprises a ring-shaped stiffener structure.

12. The IC package of claim 11, wherein the ring-shaped stiffener structure is adjacent to a perimeter of the package substrate.

13. The IC package of claim 1, wherein:
the first stiffener structure further comprises a second cavity extending adjacent to the first side of the package substrate; and
further comprising:
a second electrical component coupled to the first side of the package substrate, the second electrical component at least partially embedded in the second cavity.

14. The IC package of claim 13, wherein the first cavity and the second cavity are part of a common cavity in the first stiffener structure.

15. The IC package of claim 1, further comprising:
a second stiffener structure outside the first die in the first direction and coupled to the first side of the package substrate, the second stiffener structure comprising:
a second cavity extending adjacent to the first side of the package substrate; and
a second electrical component coupled to the first side of the package substrate, the second electrical component at least partially embedded in the second cavity.

16. The IC package of claim 1, wherein the first electrical component is electrically coupled to the first die through the package substrate.

17. The IC package of claim 1, further comprising a heat spreader structure comprising the first stiffener structure and a cover structure extending in the first direction adjacent to the first die and fully intersecting the first die in a second direction orthogonal to the first direction.

18. The IC package of claim 17, wherein the first stiffener structure and the cover structure are a monolithic structure.

19. The IC package of claim 1,
wherein the first die comprises a first chiplet; and
further comprising a second chiplet coupled to the first side of the package substrate;
wherein:
the first chiplet electrically coupled to the second chiplet through the package substrate; and
the first stiffener structure is further adjacent to the second chiplet in the first direction.

20. The IC package of claim 1 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.

21. A method of fabricating an integrated circuit (IC) package, comprising:
providing a package substrate comprising a first side extending in a first direction;
coupling a first electrical component to the first side of the package substrate;
coupling a first surface of a first stiffener structure comprising a first cavity extending adjacent to the first surface, to the first side of the package substrate such that the first cavity at least partially encloses the first electrical component; and
coupling a first die to the first side of the package substrate adjacent to the first stiffener structure in the first direction.

22. The method of claim 21, wherein coupling the first surface of the first stiffener structure further comprises not intersecting the first stiffener structure with the first die in a second direction orthogonal to the first direction.

23. The method of claim 21, wherein coupling the first surface of the first stiffener structure further comprises the first cavity not intersecting the first die in a second direction orthogonal to the first direction.

24. The method of claim 21, further comprising coupling a cover structure to the first stiffener structure extending in the first direction adjacent to the first die and fully intersecting the first die in a second direction orthogonal to the first direction.

25. The method of claim 21, further comprising coupling the first electrical component to the first side of the package substate prior to coupling the first surface of the first stiffener structure to the first side of the package substrate.

26. The method of claim 21, further comprising disposing an underfill material adjacent to the first die after coupling the first surface of the first stiffener structure to the first side of the package substrate.
